(19) United States
(12) Patent Application Publication
(10) Pub. No.: US 2015/0287839 A1
(43) Pub. Date: Oct. 8, 2015

(54) SCHOTTKY BARRIER DIODE AND METHOD OF MANUFACTURING THE SAME

(71) Applicant: SUMITOMO ELECTRIC INDUSTRIES, LTD., Osaka-shi, Osaka (JP)

(72) Inventor: Kuniaki Ishihara, Itami-shi (JP)

(21) Appl. No.: 14/440,824

(22) PCT Filed: Nov. 13, 2013
(86) PCT No.: PCT/JP2013/080678

§ 371 Date: May 5, 2015

(30) Foreign Application Priority Data
Nov. 26, 2012 (JP) 2012-257194

(51) Int. Cl. H01L 29/872; H01L 21/285; H01L 29/47; H01L 21/02; H01L 29/20; H01L 29/66

(52) U.S. Cl. CPC H01L 29/872; H01L 29/2003; H01L 29/66212; H01L 29/475; H01L 21/0254; H01L 21/28581

(57) ABSTRACT

A Schottky barrier diode includes a first electrode, a group III nitride film, an insulating film having an opening, a Schottky contact metal film, a joint metal film, a conductive support substrate, and a second electrode that are arranged in order in a direction from a first main-surface side to a second main-surface side. A part of the Schottky contact metal film can extend on a part of the insulating film. The Schottky barrier diode can further include an embedded metal film disposed between the joint metal film and a recessed portion of the Schottky contact metal film. Accordingly, there are provided the Schottky barrier diode having a high breakdown voltage and allowing large current to flow therethrough, and a method of manufacturing the same.

### TECHNICAL FIELD

The present invention relates to a Schottky barrier diode having a high breakdown voltage and allowing large current to flow therethrough, and to a method of manufacturing the same.

### BACKGROUND ART

A Schottky barrier diode (hereinafter also referred to as SBD) in which a group III nitride film is used is excellent in high-frequency characteristic, breakdown voltage characteristic, low switching loss, and the like, and therefore has been of interest in recent years. For example, Japanese Patent Laying-Open No. 2006-156457 (PTD 1) discloses a Schottky barrier diode in which a group III nitride film grown on a silicon substrate is used.

### CITATION LIST

### Patent Document

### PTD 1: Japanese Patent Laying-Open No. 2006-156457

### SUMMARY OF INVENTION

### Technical Problem

Regarding the SBD (Schottky barrier diode) disclosed in Japanese Patent Laying-Open No. 2006-156457 (PTD 1), the group III nitride film used in the SBD is grown on the silicon substrate having its chemical composition different from that of the group III nitride. Thus, the film has a high dislocation density of 1×10⁸ cm⁻² or more, which makes it difficult to keep a high breakdown voltage. Further, in order to grow, on the silicon substrate, the group III nitride film having a different chemical composition from that of the silicon substrate, it is necessary to grow a group III nitride buffer film having low crystallinity on the silicon substrate and then grow the group III nitride film on the group III nitride buffer film. Because the group III nitride buffer film has a high resistance, it is difficult to use the group III nitride buffer film in an SBD having a vertical structure allowing large current to flow therethrough.

Although the above problem can be solved by using a group III nitride substrate as a base substrate for a group III nitride film to be grown thereon, the expensive group III nitride substrate increases the cost of manufacturing an SBD.

An object of the present invention is to solve the above-described problems and provide a low-cost Schottky barrier diode having a high breakdown voltage and allowing large current to flow therethrough, as well as a method of manufacturing the same.

### Solution to Problem

According to an aspect, the present invention is a Schottky barrier diode including a first electrode, a group III nitride film, an insulating film having an opening, a Schottky contact metal film, a joint metal film, a conductive support substrate, and a second electrode that are arranged in order in a direction from a first main-surface side to a second main-surface side.

In the Schottky barrier diode according to the aspect of the present invention, a part of the Schottky contact metal film can extend on a part of the insulating film.

The Schottky barrier diode according to the aspect of the present invention can further include an embedded metal film disposed between the joint metal film and a recessed portion of the Schottky contact metal film, the recessed portion being formed by presence of the opening of the insulating film. It can further include an anti-diffusion metal film disposed between the Schottky contact metal film and the joint metal film and between the embedded metal film and the joint metal film.

The Schottky barrier diode according to the aspect of the present invention can further include an anti-diffusion metal film disposed between the Schottky contact metal film and the joint metal film. It can further include an embedded metal film disposed between the joint metal film and a recessed portion of the anti-diffusion metal film, the recessed portion being formed by presence of the opening of the insulating film.

In the Schottky barrier diode according to the aspect of the present invention, the first electrode can be located on a part of a main surface of the group III nitride film.

According to another aspect, the present invention is a method of manufacturing a Schottky barrier diode including the steps of: forming a group III nitride film on a base group III nitride film of a base composite substrate, the base composite substrate including a base support substrate and the base group III nitride film joined to one main-surface side of the base support substrate; forming an insulating film having an opening on the group III nitride film; forming a Schottky contact metal film on the group III nitride film under the opening of the insulating film and on the insulating film; obtaining a joined substrate by joining a conductive support substrate onto the Schottky contact metal film with a joint metal film interposed therebetween; removing the base composite substrate from the joined substrate; and forming a first electrode on the group III nitride film and forming a second electrode on the conductive support substrate.

Regarding the method of manufacturing a Schottky barrier diode according to the aspect of the present invention, in the step of forming a Schottky contact metal film, the Schottky contact metal film can be formed so that a part of the Schottky contact metal film extends on a part of the insulating film.

The method of manufacturing a Schottky barrier diode according to the aspect of the present invention further includes the step of forming an embedded metal film on a recessed portion of the Schottky contact metal film, after the step of forming a Schottky contact metal film and before the step of obtaining a joined substrate, and the step of obtaining a joined substrate can be performed by joining the conductive support substrate onto the Schottky contact metal film and onto the embedded metal film with the joint metal film interposed therebetween. The method further includes the step of forming an anti-diffusion metal film on the Schottky contact metal film and on the embedded metal film, after the step of forming an embedded metal film and before the step of obtaining a joined substrate, and the step of obtaining a joined substrate can be performed by joining the conductive support substrate onto the anti-diffusion metal film with the joint metal film interposed therebetween.

The method of manufacturing a Schottky barrier diode according to the aspect of the present invention further includes the step of forming an anti-diffusion metal film on the Schottky contact metal film, after the step of forming a Schottky contact metal film and before the step of obtaining a joined substrate, and the step of obtaining a joined substrate can be performed by joining the conductive support substrate onto the anti-diffusion metal film with the joint metal film interposed therebetween. The method further includes the step of forming an embedded metal film on a recessed portion of the anti-diffusion metal film, after the step of forming an anti-diffusion metal film and before the step of obtaining a joined substrate, and the step of obtaining a joined substrate can be performed by joining the conductive support substrate onto the anti-diffusion metal film and onto the embedded metal film with the joint metal film interposed therebetween.

Regarding the method of manufacturing a Schottky barrier diode according to the aspect of the present invention, the first electrode can be formed on a part of a main surface of the group III nitride film.

### Advantageous Effects of Invention

In accordance with the present invention, a low-cost Schottky barrier diode having a high breakdown voltage and allowing large current to flow, as well as a method of manufacturing the same can be provided.

### BRIEF DESCRIPTION OF DRAWINGS

FIG. 1 is a schematic cross-sectional view showing an example of the Schottky barrier diode according to the present invention.

FIG. 2 is a schematic cross-sectional view showing another example of the Schottky barrier diode according to the present invention.

FIG. 3 is a schematic cross-sectional view showing a further example of the Schottky barrier diode according to the present invention.

FIG. 4 is a schematic cross-sectional view showing a further example of the Schottky barrier diode according to the present invention.

FIG. 5 is a schematic cross-sectional view showing a further example of the Schottky barrier diode according to the present invention.

FIG. 6 is a schematic plan view showing an example of the state of arrangement of a group III nitride film, an insulating film having an opening, and a Schottky barrier metal film in the Schottky barrier diode according to the present invention.

FIG. 7 is a schematic plan view showing another example of the state of arrangement of a group III nitride film, an insulating film having an opening, and a Schottky barrier metal film in the Schottky barrier diode according to the present invention.

FIG. 8 is a schematic plan view showing a further example of the state of arrangement of a group III nitride film, an insulating film having an opening, and a Schottky barrier metal film in the Schottky barrier diode according to the present invention.

FIG. 9 is a schematic cross-sectional view showing an example of the method of manufacturing a Schottky barrier diode according to the present invention.

FIG. 10 is a schematic cross-sectional view showing another example of the method of manufacturing a Schottky barrier diode according to the present invention.

FIG. 11 is a schematic cross-sectional view showing a further example of the method of manufacturing a Schottky barrier diode according to the present invention.

FIG. 12 is a schematic cross-sectional view showing a further example of the method of manufacturing a Schottky barrier diode according to the present invention.

FIG. 13 is a schematic cross-sectional view showing a further example of the method of manufacturing a Schottky barrier diode according to the present invention.

FIG. 14 is a schematic cross-sectional view showing an example of the method of manufacturing a base composite substrate used for the method of manufacturing a Schottky barrier diode according to the present invention.

### DESCRIPTION OF EMBODIMENTS

[Schottky Barrier Diode]

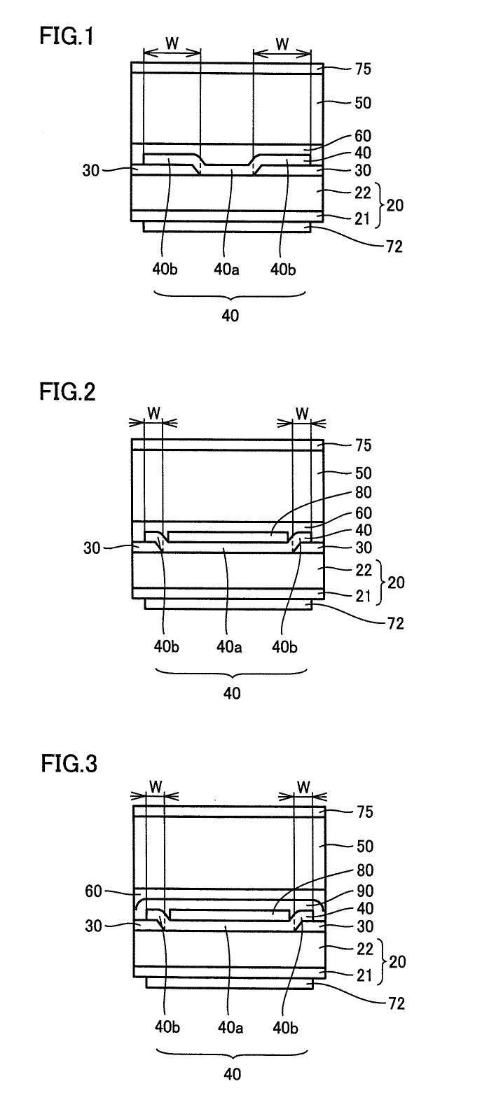

Referring to FIGS. 1 to 5, an SBD (Schottky barrier diode) in an embodiment of the present invention includes a first electrode 72, a group III nitride film 20, an insulating film 30 having an opening, a Schottky contact metal film 40, a joint metal film 60, a conductive support substrate 50, and a second electrode 75 that are arranged in order in a direction from a first main-surface side to a second main-surface side.

In the SBD of the present embodiment, first electrode 72, group III nitride film 20, insulating film 30 having an opening, Schottky contact metal film 40, joint metal film 60, conductive support substrate 50, and second electrode 75 are arranged in this order, and therefore, the SBD has a high breakdown voltage and allows large current to flow therethrough.

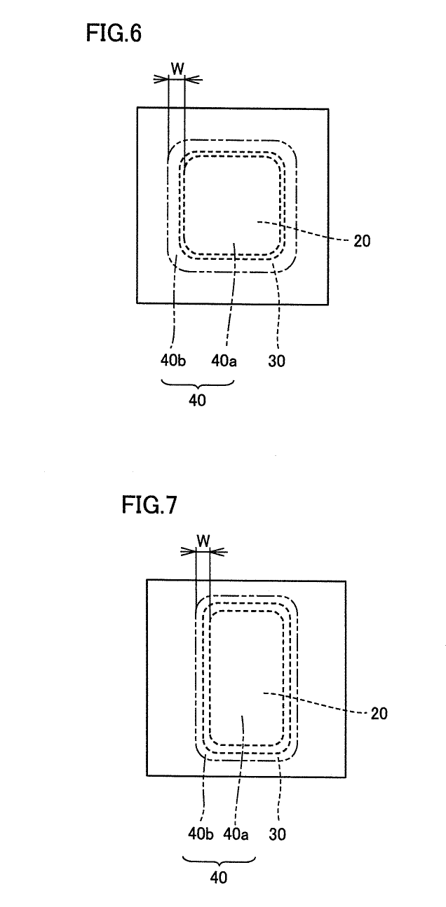

Referring to FIGS. 6 to 8 in addition to FIGS. 1 to 5, in the SBD of the present embodiment, preferably a part of Schottky contact metal film 40 extends on a part of insulating film 30. In this case, Schottky contact metal film 40 has a Schottky contact portion 40a located in contact with the upper side of group III nitride film 20 under the opening of insulating film 30, and an insulating contact portion 40b located in contact with the upper side of a peripheral portion of the opening that is a part of insulating film 30. Accordingly, electric field concentration on an edge of Schottky contact portion 40a of Schottky contact metal film 40 is alleviated and no gap is present between Schottky contact metal film 40 and insulating film 30, and therefore, the SBD with a high breakdown voltage is obtained. If a part of Schottky contact metal film 40 does not extend on a part of the insulating film, electric field concentration on the edge of Schottky contact metal film 40 occurs and a gap is present between Schottky contact metal film 40 and insulating film 30. Because such a gap is filled with a metal material (Sn alloy for example) having a high adhesiveness and a small work function and because a portion where the metal material and the group III nitride film contact each other is located close to an ohmic contact, improvement of the breakdown voltage of the SBD is hindered.

In the SBD of the present embodiment, the part of Schottky contact metal film 40 that extends on a part of insulating film 30 has a width W (namely width W of insulating contact portion 40b of Schottky contact metal film 40) of preferably 1 μm or more and 100 μm or less and more preferably 5 μm or more and 30 μm or less, in order to ensure the adherence between the part of Schottky contact metal film 40 that extends on a part of insulating film 30 and this part of insulating film 30, and not to unnecessarily occupy an area which does not contribute to current.

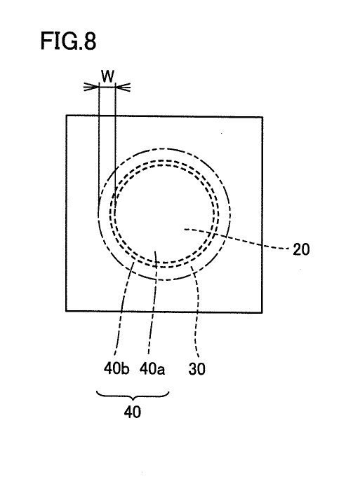

Referring to FIGS. 6 to 8, in the SBD of the present embodiment, the shape in plan view of the opening of insulating film 30 and the shape of a main surface of Schottky contact metal film 40 are not particularly limited. In order to alleviate electric field concentration on an edge of Schottky contact portion 40a of Schottky contact metal film 40 and to allow the functioning main surface to have a large area, the shapes are preferably at least one of a polygon having arc-shaped vertexes, a circle, and an ellipse. For example, the shapes are preferably a square having arc-shaped vertexes (FIG. 6), a rectangle having arc-shaped vertexes (FIG. 7), a circle (FIG. 8), or the like. Regarding the two-dimensional size of the opening of insulating film 30, in order to stably form the opening of insulating film 30 and to allow insulating contact portion 40b of Schottky contact metal film 40 to have an appropriate process margin required for fabrication into a chip, the size of the opening defined by the distance between two sides opposite to each other or the radial dimension is as follows. The shortest distance or the shortest radial dimension is preferably 50 μm or more and more preferably 200 μm or more, and the longest distance or the longest radial dimension is preferably (chip width—60) μm or less and more preferably (chip width—100) μm or less. For example, in the case where the chip has a square shape of 1500 μm (chip width)×1500 μm (chip width), the longest distance is preferably 1440 μm or less and more preferably 1400 μm or less. In the following, specific embodiments will be described.

### First Embodiment

Referring to FIG. 1, an SBD in a first embodiment of the present invention includes first electrode 72, group III nitride film 20, insulating film 30 having an opening, Schottky contact metal film 40, joint metal film 60, conductive support substrate 50, and second electrode 75 that are arranged in order in a direction from a first main-surface side to a second main-surface side. A part of Schottky contact metal film 40 extends on a part of insulating film 30. As described above, the SBD of the first embodiment can have a high breakdown voltage and allow large current to flow therethrough.

First electrode 72 is not particularly limited. In order to achieve a satisfactory electrical connection with group III nitride film 20 and an external electrode (not shown), however, first electrode 72 preferably has an electrode structure including an Al layer and an Au layer located in order from the group III nitride film 20 side. In consideration of the adherence between group III nitride film 20, first electrode 72, and an external electrode, first electrode 72 herein has a four-layer structure made up of a Ti layer, an Al layer, a Ti layer, and an Au layer located in order from group III nitride film 20. Further, second electrode 75 is not particularly limited. In order to achieve a satisfactory electrical connection with conductive support substrate 50 and an external electrode (not shown), however, second electrode 75 herein has a three-layer structure made up of a Ti layer, a Pt layer, and an Au layer located in order from the conductive support substrate 50 side.

Group III nitride film 20 is not particularly limited. In order to achieve a high breakdown voltage, however, group III nitride film 20 preferably has a dislocation density of 1×10⁶ cm⁻² or less. Group III nitride film 20 having such a low dislocation density is obtained by growing it on a base group III nitride film of a base composite substrate which includes a base support substrate and the base group III nitride film joined to one main-surface side of the base support substrate, as illustrated later in connection with a sixth embodiment. For the purpose of forming a Schottky junction between group III nitride film 20 and Schottky contact metal film 40 and forming an ohmic junction between group III nitride film 20 and first electrode 72 at the same time, preferably group III nitride film 20 includes an n⁺-group III nitride layer 21 having a relatively high donor concentration and formed on the first electrode 72 side and an n-group III nitride layer 22 having a relatively low donor concentration and formed on the opposite side.

Insulating film 30 having an opening is not particularly limited. In order to achieve high insulation of insulating film 30 which is a non-opening portion, however, insulating film 30 is preferably SiO₂ film, Si₃N₄ film, or the like.

Schottky contact metal film 40 is not particularly limited as long as it forms a Schottky contact with group III nitride film 20. In order to have an appropriate difference between a work function of a metal forming the metal film and a Fermi level of a group III nitride forming the group III nitride film, however, Schottky contact metal film 40 is preferably Ni/Au film, Ti/Au film, Pt/Au film, or the like.

Joint metal film 60 is not particularly limited. In order to achieve a high joining ability with Schottky contact metal film 40 as well as an embedded metal film and an anti-diffusion metal film which will be described later herein, however, joint metal film 60 preferably includes an Au—Sn alloy layer. Further, in order to prevent diffusion of Sn from the Au—Sn alloy layer into conductive support substrate 50, joint metal film 60 preferably includes, between the Au—Sn alloy layer of joint metal film 60 and conductive support substrate 50, three layers, namely an Ni layer, a Pt layer, and an Au layer arranged in order from the conductive support substrate 50 side.

Conductive support substrate 50 is not particularly limited. In order to have a high electrical conductivity, however, conductive support substrate 50 is preferably silicon (Si) substrate, germanium (Ge) substrate, silicon carbide (SiC) substrate or the like, and further preferably copper (Cu) substrate, molybdenum (Mo) substrate, tungsten (W) substrate, copper-tungsten (Cu—W) alloy substrate or the like having a high thermal conductivity in addition to a high electrical conductivity.

In the SBD of the first embodiment, Schottky contact metal film 40 is disposed on insulating film 30 which has an opening and is disposed on group III nitride film 20, and a part of Schottky contact metal film 40 extends on a part of insulating film 30. Therefore, in Schottky contact metal film 40, Schottky contact portion 40a located in contact with the upper side of group III nitride film 20 under the opening of insulating film 30 is recessed relative to insulating contact portion 40b located in contact with the upper side of insulating film 30. The recessed portion of Schottky contact metal film 40, however, is filled with joint metal film 60. Particularly in the case where the opening of insulating film 30 is small, the recessed portion of Schottky contact metal film 40 is completely filled with joint metal film 60.

### Second Embodiment

Referring to FIG. 2, an SBD in a second embodiment of the present invention includes first electrode 72, group III nitride film 20, insulating film 30 having an opening, Schottky contact metal film 40, an embedded metal film 80, joint metal film 60, conductive support substrate 50, and second electrode 75 that are arranged in order in a direction from a first main-surface side to a second main-surface side. A part of Schottky contact metal film 40 extends on a part of insulating film 30. Namely, the SBD of the second embodiment additionally includes, relative to the SBD of the first embodiment, embedded metal film 80 disposed between joint metal film 60 and the recessed portion of Schottky contact metal film 40, where the recessed portion is formed by the presence of the opening of insulating film 30.

The SBD of the second embodiment, like the SBD of the first embodiment, can have a high breakdown voltage and allow large current to flow. First electrode 72, group III nitride film 20, insulating film 30 having an opening, Schottky contact metal film 40, joint metal film 60, conductive support substrate 50, and second electrode 75 in the SBD of the second embodiment are similar to first electrode 72, group III nitride film 20, insulating film 30 having an opening, Schottky contact metal film 40, joint metal film 60, conductive support substrate 50, and second electrode 75, respectively, in the SBD of the first embodiment.

In the SBD of the second embodiment, Schottky contact metal film 40 is disposed on insulating film 30 which has an opening and is disposed on group III nitride film 20, and a part of Schottky contact metal film 40 extends on a part of insulating film 30. Therefore, in Schottky contact metal film 40, Schottky contact portion 40a located in contact with the upper side of group III nitride film 20 under the opening of insulating film 30 is recessed relative to insulating contact portion 40b located in contact with the upper side of insulating film 30. Therefore, if the opening of insulating film 30 is large, a gap may be present between the recessed portion of Schottky contact metal film 40 and joint metal film 60. Then, embedded metal film 80 is disposed between the recessed portion of Schottky contact metal film 40 and joint metal film 60 so that embedded metal film 80 completely fills the space between the recessed portion of Schottky contact metal film 40 and joint metal film 60. In this way, occurrence of any gap between the recessed portion and joint metal film 60 can be prevented. Accordingly, the SBD can be improved in terms of the ON resistance, the breakdown voltage, and the yield determined by the appearance depending on for example whether group III nitride film 20 peels off or not, for example.

Embedded metal film 80 is not particularly limited. In order to have a work function close to Schottky contact metal film 40, however, embedded metal film 80 preferably has a double-layer structure made up of an Ni layer and an Au layer in order from the Schottky contact metal film 40 side.

### Third Embodiment

Referring to FIG. 3, an SBD in a third embodiment of the present invention includes first electrode 72, group III nitride film 20, insulating film 30 having an opening, Schottky contact metal film 40, embedded metal film 80, an anti-diffusion metal film 90, joint metal film 60, conductive support substrate 50, and second electrode 75 that are arranged in order in a direction from a first main-surface side to a second main-surface side. A part of Schottky contact metal film 40 extends on a part of insulating film 30. Namely, the SBD of the third embodiment additionally includes, relative to the SBD of the second embodiment, anti-diffusion metal film 90 disposed between Schottky contact metal film 40 and joint metal film 60 and between embedded metal film 80 and joint metal film 60.

The SBD of the third embodiment, like the SBD of the first embodiment, can have a high breakdown voltage and allow large current to flow. In addition, like the SBD of the second embodiment, the SBD of the third embodiment can have embedded metal film 80 which completely fills the space between the recessed portion of Schottky contact metal film 40 and joint metal film 60 to thereby prevent any gap therebetween. Accordingly, the SBD can be improved in terms of the ON resistance, the breakdown voltage, and the yield determined by the appearance depending on for example whether group III nitride film 20 peels off or not, for example.

First electrode 72, group III nitride film 20, insulating film 30 having an opening, Schottky contact metal film 40, joint metal film 60, conductive support substrate 50, and second electrode 75 in the SBD of the third embodiment are similar to first electrode 72, group III nitride film 20, insulating film 30 having an opening, Schottky contact metal film 40, joint metal film 60, conductive support substrate 50, and second electrode 75, respectively, in the SBD of the first embodiment. Embedded metal film 80 in the SBD of the third embodiment is similar to embedded metal film 80 in the SBD of the second embodiment.

In the SBD of the third embodiment, anti-diffusion metal film 90 is disposed between Schottky contact metal film 40 and joint metal film 60 and between embedded metal film 80 and joint metal film 60, and therefore, diffusion of metal atoms in joint metal film 60 into Schottky contact metal film 40 and into embedded metal film 80 can be prevented. Accordingly, the SBD is improved in terms of the forward threshold voltage, the ON resistance, the breakdown voltage, and the like.

Anti-diffusion metal film 90 is not particularly limited. In the case where an Au—Sn alloy layer is included in joint metal film 60, anti-diffusion metal film 90 preferably includes three layers, namely an Ni layer, a Pt layer, and an Au layer disposed in order from the Schottky contact metal film 40 side and the embedded metal film 80 side, in order to prevent diffusion of Sn from the Au—Sn alloy layer.

### Fourth Embodiment

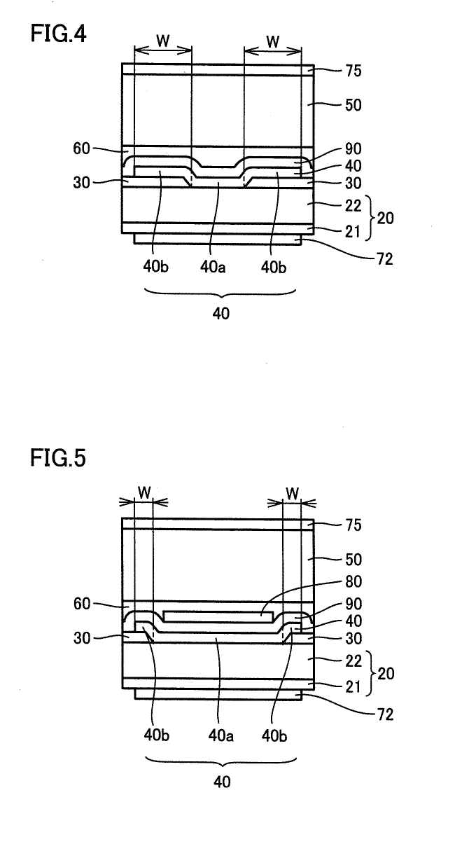

Referring to FIG. 4, an SBD in a fourth embodiment of the present invention includes first electrode 72, group III nitride film 20, insulating film 30 having an opening, Schottky contact metal film 40, anti-diffusion metal film 90, joint metal film 60, conductive support substrate 50, and second electrode 75 that are arranged in order in a direction from a first main-surface side to a second main-surface side. A part of Schottky contact metal film 40 extends on a part of insulating film 30. Namely, the SBD of the fourth embodiment additionally includes, relative to the SBD of the first embodiment, anti-diffusion metal film 90 disposed between Schottky contact metal film 40 and joint metal film 60.

The SBD of the fourth embodiment, like the SBD of the first embodiment, can have a high breakdown voltage and allow large current to flow. First electrode 72, group III nitride film 20, insulating film 30 having an opening, Schottky contact metal film 40, joint metal film 60, conductive support substrate 50, and second electrode 75 in the SBD of the fourth embodiment are similar to first electrode 72, group III nitride film 20, insulating film 30 having an opening, Schottky contact metal film 40, joint metal film 60, conductive support substrate 50, and second electrode 75, respectively, in the SBD of the first embodiment.

In the SBD of the fourth embodiment, anti-diffusion metal film 90 is disposed between Schottky contact metal film 40 and joint metal film 60, and therefore, diffusion of metal atoms in joint metal film 60 into Schottky contact metal film 40 can be prevented. Accordingly, the SBD is improved in terms of the forward threshold voltage, the ON resistance, the breakdown voltage, and the like.

Anti-diffusion metal film 90 in the SBD of the fourth embodiment is similar to anti-diffusion metal film 90 in the SBD of the third embodiment.

In the SBD of the fourth embodiment, insulating film 30 having an opening is disposed on group III nitride film 20, Schottky contact metal film 40 is disposed on insulating film 30 having the opening, and anti-diffusion metal film 90 is disposed on Schottky contact metal film 40. Further, a part of Schottky contact metal film 40 extends on a part of insulating film 30. Therefore, in Schottky contact metal film 40, Schottky contact portion 40a located in contact with the upper side of group III nitride film 20 under the opening of insulating film 30 is recessed relative to insulating contact portion 40b located in contact with the upper side of insulating film 30. In anti-diffusion metal film 90, a part formed on the recessed portion of Schottky contact metal film 40 is recessed relative to a part formed on a portion other than the recessed portion of Schottky contact metal film 40. The recessed portion of anti-diffusion metal film 90, however, is filled with joint metal film 60. Particularly in the case where the opening of insulating film 30 is small, the recessed portion of anti-diffusion metal film 90 is completely filled with joint metal film 60.

### Fifth Embodiment

Referring to FIG. 5, an SBD in a fifth embodiment of the present invention includes first electrode 72, group III nitride film 20, insulating film 30 having an opening, Schottky contact metal film 40, anti-diffusion metal film 90, embedded metal film 80, joint metal film 60, conductive support substrate 50, and second electrode 75 that are arranged in order in a direction from a first main-surface side to a second main-surface side. A part of Schottky contact metal film 40 extends on a part of insulating film 30. Namely, the SBD of the fifth embodiment additionally includes, relative to the SBD of the fourth embodiment, embedded metal film 80 disposed between the recessed portion of anti-diffusion metal film 90 and joint metal film 60, where the recessed portion is formed by the presence of the opening of insulating film 30.

The SBD of the fifth embodiment, like the SBD of the fourth embodiment, can have a high breakdown voltage and allow large current to flow. In addition, diffusion of metal atoms in joint metal film 60 into Schottky contact metal film 40 can be prevented. Accordingly, the SBD is improved in terms of the forward threshold voltage, the ON resistance, the breakdown voltage, and the like.

First electrode 72, group III nitride film 20, insulating film 30 having an opening, Schottky contact metal film 40, joint metal film 60, conductive support substrate 50, and second electrode 75 in the SBD of the fifth embodiment are similar to first electrode 72, group III nitride film 20, insulating film 30 having an opening, Schottky contact metal film 40, joint metal film 60, conductive support substrate 50, and second electrode 75, respectively, in the SBD of the first embodiment. Anti-diffusion metal film 90 in the SBD of the fifth embodiment is also similar to anti-diffusion metal film 90 in the SBD of the fourth embodiment.

In the SBD of the fifth embodiment, insulating film 30 having an opening is disposed on group III nitride film 20, Schottky contact metal film 40 is disposed on insulating film 30 having the opening, anti-diffusion metal film 90 is disposed on Schottky contact metal film 40, and a part of Schottky contact metal film 40 extends on a part of insulating film 30. Therefore, in Schottky contact metal film 40, Schottky contact portion 40a located in contact with the upper side of group III nitride film 20 under the opening of insulating film 30 is recessed relative to insulating contact portion 40b located in contact with the upper side of insulating film 30. In anti-diffusion metal film 90, a part formed on the recessed portion of Schottky contact metal film 40 is recessed relative to a part formed on a portion other than the recessed portion of Schottky contact metal film 40. Therefore, if the opening of insulating film 30 is large, a gap may be present between the recessed portion of anti-diffusion metal film 90 and joint metal film 60. Then, embedded metal film 80 is disposed between the recessed portion of anti-diffusion metal film 90 and joint metal film 60 so that embedded metal film 80 completely fills the space between the recessed portion of anti-diffusion metal film 90 and joint metal film 60. In this way, occurrence of any gap therebetween can be prevented. Accordingly, the SBD can be improved in terms of the ON resistance, the breakdown voltage, and the yield determined by the appearance depending on for example whether group III nitride film 20 peels off or not, for example.

Embedded metal film 80 in the SBD of the fifth embodiment is similar to embedded metal film 80 in the SBD of the second embodiment.

Referring to FIGS. 1 to 8, in order to facilitate alignment in fabrication of the above-described SBD of the first to fifth embodiments each into a chip, preferably first electrode 72 is patterned so that first electrode 72 is located on a part of a main surface of group III nitride film 20. If first electrode 72 is formed on the whole surface of group III nitride film 20, arrangement of Schottky contact metal film 40 is invisible, which makes the alignment difficult in fabrication of the diode into a chip.

[Method of Manufacturing Schottky Barrier Diode]

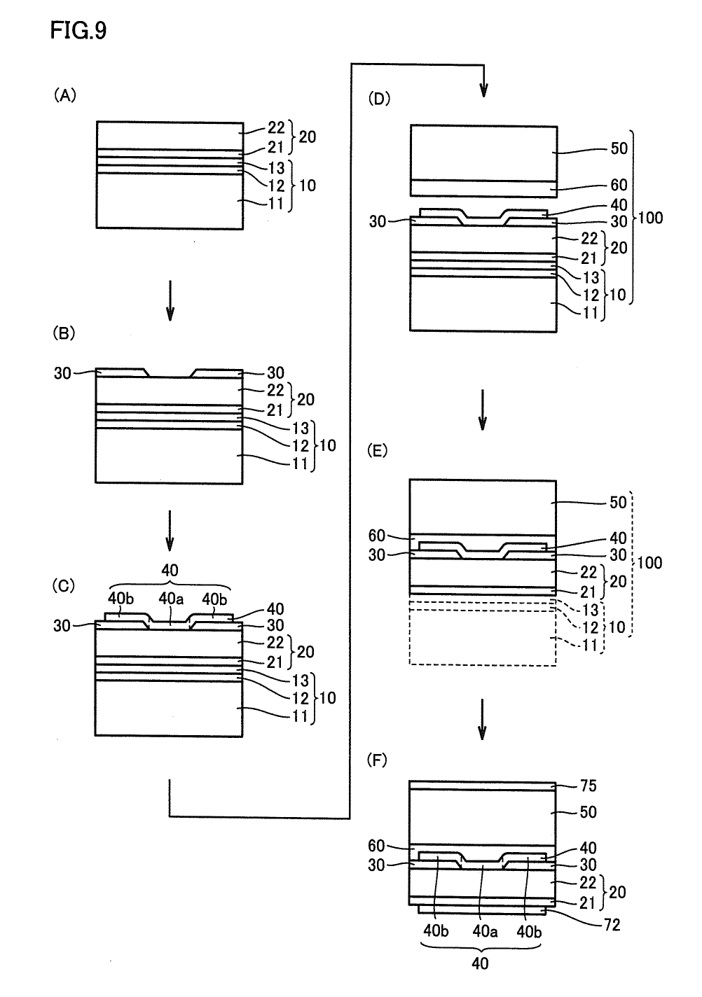

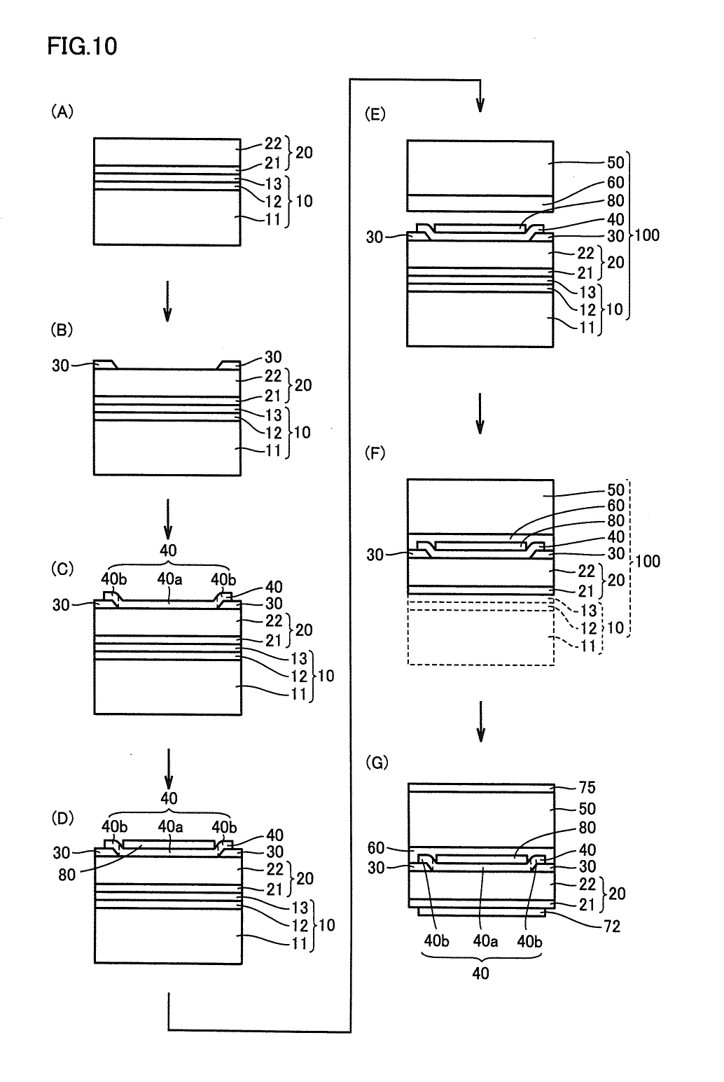

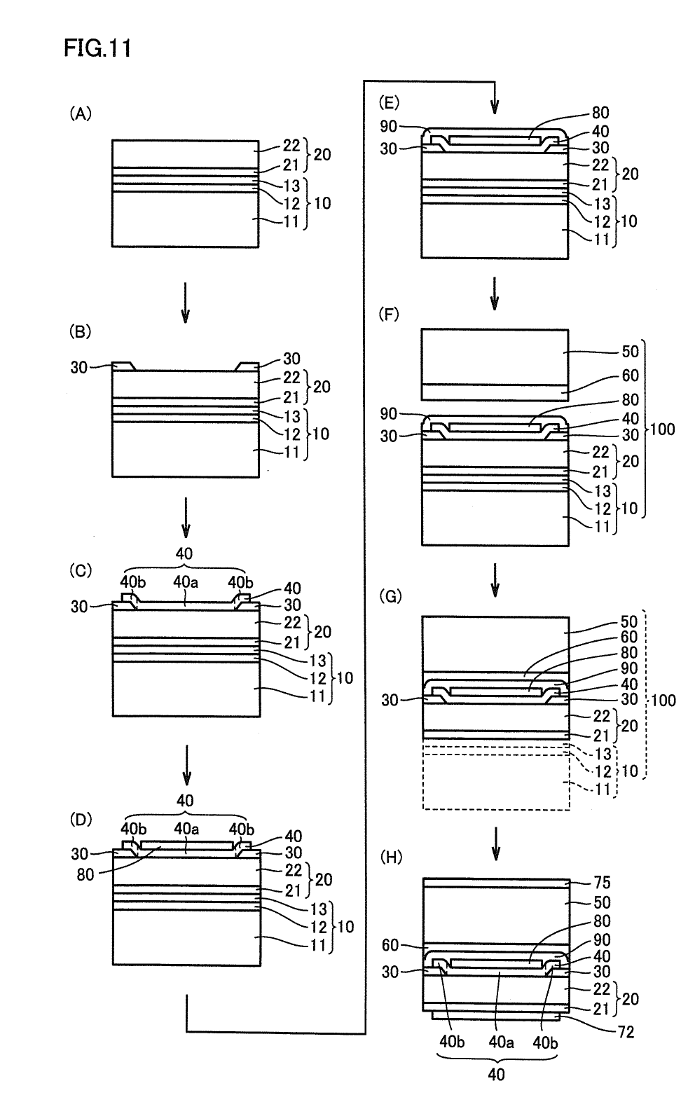

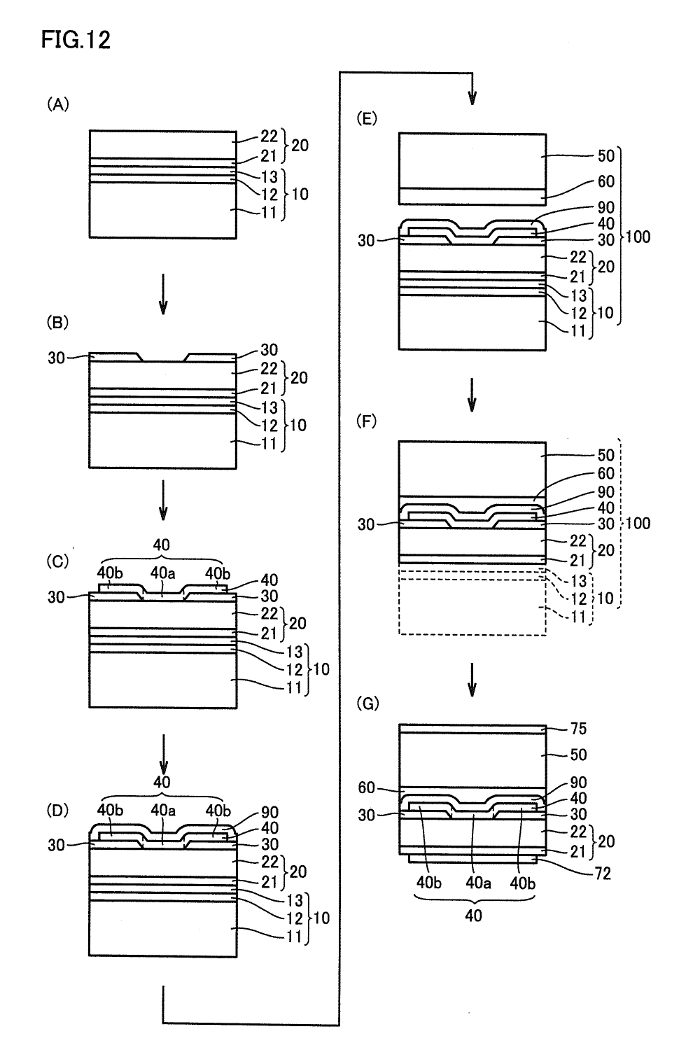

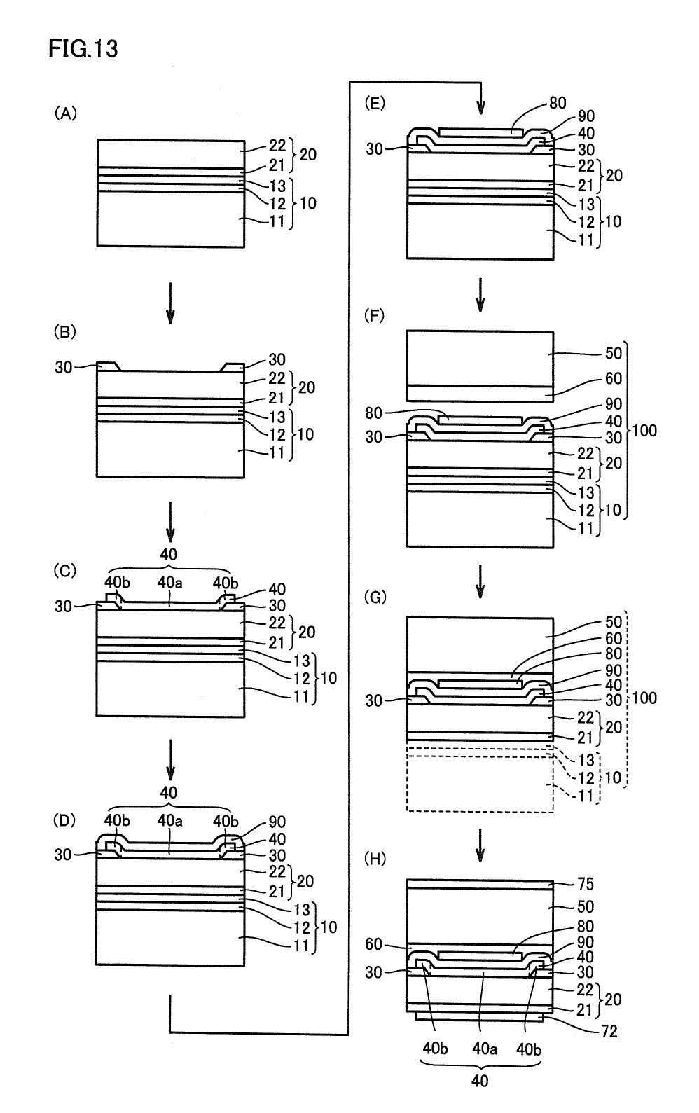

Referring to FIGS. 9 to 13, a method of manufacturing an SBD (Schottky barrier diode) in another embodiment of the present invention includes the steps of: forming a group III nitride film 20 on a base group III nitride film 13 of a base composite substrate 10, base composite substrate 10 including a base support substrate 11 and base group III nitride film 13 joined to one main-surface side of base support substrate 11 ((A) in FIGS. 9 to 13); forming an insulating film 30 having an opening on group III nitride film 20 ((B) in FIGS. 9 to 13); forming a Schottky contact metal film 40 on group III nitride film 20 under the opening of insulating film 30 and on insulating film 30 ((C) in FIGS. 9 to 13); obtaining a joined substrate 100 by joining a conductive support substrate 50 onto Schottky contact metal film 40 with a joint metal film 60 interposed therebetween (FIG. 9 (D), FIG. 10 (E), FIG. 11 (F), FIG. 12 (E), and FIG. 13 (F)); removing base composite substrate 10 from joined substrate 100 (FIG. 9 (E), FIG. 10 (F), FIG. 11 (G), FIG. 12 (F), and FIG. 13 (G)); and forming a first electrode 72 on group III nitride film 20 and forming a second electrode 75 on conductive support substrate 50 (FIG. 9 (F), FIG. 10 (G), FIG. 11 (H), FIG. 12 (G), and FIG. 13 (H)).

The method of manufacturing an SBD in the present embodiment includes the above-described steps to thereby enable the Schottky barrier diode having a high breakdown voltage and allowing large current to flow to be manufactured at low cost.

Referring to FIGS. 6 to 8 in addition to FIGS. 9 to 13, in the step of forming a Schottky contact metal film in the method of manufacturing an SBD in the present embodiment, preferably Schottky contact metal film 40 is formed so that a part of Schottky contact metal film 40 extends on a part of insulating film 30. In this case, Schottky contact metal film 40 has a Schottky contact portion 40a located in contact with the upper side of group III nitride film 20 under the opening of insulating film 30, and an insulating contact portion 40b located in contact with the upper side of a peripheral portion of the opening that is a part of insulating film 30. Accordingly, electric field concentration on an edge of Schottky contact portion 40a of Schottky contact metal film 40 is alleviated and no gap is present between Schottky contact metal film 40 and insulating film 30, and therefore, the SBD with a high breakdown voltage is obtained. If a part of Schottky contact metal film 40 does not extend on a part of the insulating film, electric field concentration on the edge of Schottky contact metal film 40 occurs and a gap is present between Schottky contact metal film 40 and insulating film 30. Because such a gap is filled with a metal material (Sn alloy for example) having a high adhesiveness and a small work function and because a portion where the metal material and the group III nitride film contact each other is located close to an ohmic contact, improvement of the breakdown voltage of the SBD is hindered. In the following, specific embodiments will be described.

### Sixth Embodiment

Referring to FIG. 9, a method of manufacturing an SBD in a sixth embodiment of the present invention refers to a method of manufacturing the SBD in the first embodiment, and includes the steps of: forming group III nitride film 20 on base group III nitride film 13 of base composite substrate 10, base composite substrate 10 including base support substrate 11 and base group III nitride film 13 joined to one main-surface side of base support substrate 11 (FIG. 9 (A)); forming insulating film 30 having an opening on group III nitride film 20 (FIG. 9 (B)); forming Schottky contact metal film 40 on group III nitride film 20 under the opening of insulating film 30 and on insulating film 30 (FIG. 9 (C)); obtaining joined substrate 100 by joining conductive support substrate 50 onto Schottky contact metal film 40 with joint metal film 60 interposed therebetween (FIG. 9 (D)); removing base composite substrate 10 from joined substrate 100 (FIG. 9 (E)); and forming first electrode 72 on group III nitride film 20 and forming second electrode 75 on conductive support substrate 50 (FIG. 9 (F)). In the step of forming Schottky contact metal film 40 (FIG. 9 (C)), Schottky contact metal film 40 is formed so that a part of Schottky contact metal film 40 extends on a part of insulating film 30.

The method of manufacturing an SBD in the sixth embodiment includes the above-described steps to thereby enable the Schottky barrier diode having a high breakdown voltage and allowing large current to flow to be manufactured at low cost.

Referring to FIG. 9 (A), base composite substrate 10 used in the step of forming group III nitride film 20 on base group III nitride film 13 of base composite substrate 10 has base group III nitride film 13 joined to one main-surface side of base support substrate 11 which can be manufactured at low cost, and therefore is of low cost. On its base group III nitride film 13, the group III nitride film having a low dislocation density and high crystallinity can be grown.

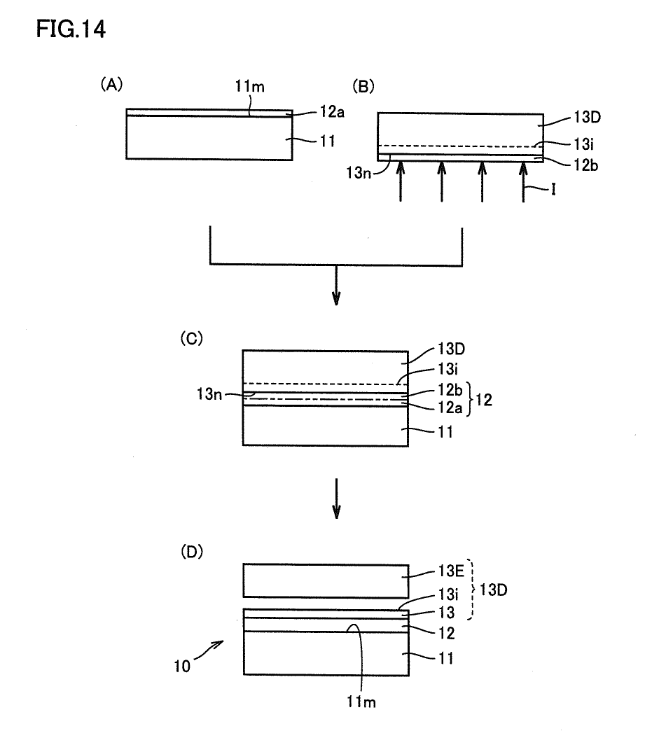

Referring now to FIG. 14, the step of preparing base composite substrate 10 is not particularly limited. In order to efficiently join base group III nitride film 13 having a low dislocation density and high crystallinity to the one main surface 11m side of base support substrate 11, however, the step of preparing it preferably includes the sub steps of: forming a base joint film 12a on main surface 11m of base support substrate 11 (FIG. 14 (A)); forming a base joint film 12b on a main surface 13n of a base group III nitride film mother substrate 13D and forming an ion implantation region 13i at a predetermined depth from main surface 13n of base group III nitride film mother substrate 13D (FIG. 14 (B)); bonding base joint film 12a formed on base support substrate 11 and base joint film 12b formed on base group III nitride film mother substrate 13D together (FIG. 14 (C)); and separating base group III nitride film mother substrate 13D along ion implantation region 13i into base group III nitride film 13 and a remaining base group III nitride film mother substrate 13E to thereby form base composite substrate 10 in which base group III nitride film 13 is joined onto one main surface 11m of base support substrate 11 with base joint film 12 interposed therebetween (FIG. 14 (D)).

Base support substrate 11 of base composite substrate 10 is not particularly limited. In order to grow group III nitride film 20 having a low dislocation density and high crystallinity on base group III nitride film 13 of base composite substrate 10 without causing cracks, however, preferably base support substrate 11 has a thermal expansion coefficient equal to a thermal expansion coefficient of base group III nitride film 13 and a thermal expansion coefficient of group III nitride film 20, or the absolute value of a difference between these thermal expansion coefficients is 2×10⁻⁶ K⁻¹ or less. Specifically, the base support substrate is preferably molybdenum substrate, mullite (Al₂O₃—SiO₂) substrate, yttria stabilized zirconia-mullite substrate, or the like.

The method of forming group III nitride film 20 on base group III nitride film 13 of base composite substrate 10 is not particularly limited. In order to epitaxially grow group III nitride film 20 having a low dislocation density and high crystallinity, however, the method is preferably HVPE (hydride vapor phase epitaxy), MOCVD (metal organic chemical vapor deposition), MBE (molecular beam epitaxy), or the like.

Referring to FIG. 9 (B), the step of forming insulating film 30 having an opening on group III nitride film 20 is not particularly limited. This step, however, preferably includes the sub step of forming insulating film 30 and the sub step of forming an opening in insulating film 30. The method of forming insulating film 30 is not particularly limited, and plasma CVD (chemical vapor deposition), sputtering, or the like can be applied. The method of forming an opening in insulating film 30 is not particularly limited, and a method of etching insulating film 30 by means of a resist mask (not shown) formed by photolithography, or the like can be applied.

Referring to FIG. 9 (C), in the step of forming Schottky contact metal film 40 on group III nitride film 20 under the opening of insulating film 30 and on insulating film 30, the method of forming Schottky contact metal film 40 is not particularly limited, and the following method or the like can be applied. Specifically, photolithography is used to form a resist mask (not shown). A metal film made up of a plurality of layers is formed thereon by EB (electron beam) vapor deposition, resistance-heating vapor deposition, sputtering, or the like, and patterned by lifting off the resist mask, and thereafter the metal film made up of a plurality of layers is annealed into an alloy.

Schottky contact metal film 40 thus obtained is formed on group III nitride film 20 under the opening of insulating film 30 and on insulating film 30, and a part of Schottky contact metal film 40 extends on a part of insulating film 30. Therefore, in Schottky contact metal film 40, Schottky contact portion 40a located in contact with the upper side of group III nitride film 20 under the opening of insulating film 30 is recessed relative to insulating contact portion 40b located in contact with the upper side of insulating film 30.

Referring to FIG. 9 (D), the step of obtaining joined substrate 100 by joining conductive support substrate 50 onto Schottky contact metal film 40 with joint metal film 60 interposed therebetween is not particularly limited. In order to efficiently obtain joined substrate 100, however, this step preferably includes the sub step of forming on conductive support substrate 50 joint metal film 60 by EB vapor deposition, resistance-heating vapor deposition, sputtering, or the like, and the sub step of bonding Schottky contact metal film 40 and joint metal film 60 together by means of a wafer bonder. At this time, the recessed portion of Schottky contact metal film 40 is filled with joint metal film 60. Particularly in the case where the opening of insulating film 30 is small, the recessed portion of Schottky contact metal film 40 is completely filled with joint metal film 60.

Referring to FIG. 9 (E), the step of removing base composite substrate 10 from joined substrate 100 is not particularly limited. This step is performed for example by removing base support substrate 11, base joint film 12, and base group III nitride film 13 which constitute base composite substrate 10. The methods of removing base support substrate 11, base joint film 12, and base group III nitride film 13 vary depending on the types of the materials forming them. For example, in the case where base support substrate 11 is molybdenum substrate, it is removed through etching with nitric acid or the like. In the case where base support substrate 11 is mullite substrate or yttria stabilized zirconium-mullite substrate, it is removed through etching with hydrofluoric acid or the like. In the case where base joint film 12 is SiO₂ film or Si₃N₄ film, it is removed through etching with hydrofluoric acid or the like. Base group III nitride film 13 is removed through ICP (inductively coupled plasma)—RIE (reactive ion etching) or the like using chlorine gas as an etching gas.

Referring to FIG. 9 (F), the step of forming first electrode 72 on group III nitride film 20 and forming second electrode 75 on conductive support substrate 50 is not particularly limited. For example, a resist mask (not shown) formed by photolithography is used to form a metal film made up of a plurality of layers through EB vapor deposition, resistance-heating vapor deposition, sputtering, or the like, and thereafter it is annealed. In this way, first electrode 72 is formed by patterning so that first electrode 72 is located on a part of a main surface of group III nitride film 20. The method of forming second electrode 75 is not particularly limited. For example, a metal film made up of a plurality of layers is formed through EB vapor deposition, resistance-heating vapor deposition, sputtering, or the like and thereafter annealed.

Further, the multi-film substrate obtained through the above-described steps is fabricated into a chip to thereby obtain the SBD of the first embodiment.

### Seventh Embodiment

Referring to FIG. 10, a method of manufacturing an SBD in a seventh embodiment of the present invention refers to a method of manufacturing the SBD in the second embodiment, and includes the steps of: forming group III nitride film 20 on base group III nitride film 13 of base composite substrate 10, base composite substrate 10 including base support substrate 11 and base group III nitride film 13 joined to one main-surface side of base support substrate 11 (FIG. 10 (A)); forming insulating film 30 having an opening on group III nitride film 20 (FIG. 10 (B)); forming Schottky contact metal film 40 on group III nitride film 20 under the opening of insulating film 30 and on insulating film 30 (FIG. 10 (C)); forming embedded metal film 80 on a recessed portion of Schottky contact metal film 40 (FIG. 10 (D)); obtaining joined substrate 100 by joining conductive support substrate 50 onto Schottky contact metal film 40 and onto embedded metal film 80 with joint metal film 60 interposed therebetween (FIG. 10 (E)); removing base composite substrate 10 from joined substrate 100 (FIG. 10 (F)); and forming first electrode 72 on group III nitride film 20 and forming second electrode 75 on conductive support substrate 50 (FIG. 10 (G)). In the step of forming Schottky contact metal film 40 (FIG. 10 (C)), Schottky contact metal film 40 is formed so that a part of the Schottky contact metal film extends on a part of the insulating film.

Namely, the method of manufacturing an SBD in the seventh embodiment additionally includes, relative to the method of manufacturing an SBD in the sixth embodiment, the step of forming embedded metal film 80 on a recessed portion of Schottky contact metal film 40, after the step of forming Schottky contact metal film 40 and before the step of obtaining joined substrate 100, and the step of obtaining joined substrate 100 is performed by joining conductive support substrate 50 onto Schottky contact metal film 40 and onto embedded metal film 80 with joint metal film 60 interposed therebetween.

The method of manufacturing an SBD in the seventh embodiment includes the above-described steps to thereby enable the Schottky barrier diode having a high breakdown voltage and allowing large current to flow to be manufactured at low cost, like the method of manufacturing an SBD in the sixth embodiment.

Further, regarding the method of manufacturing an SBD in the seventh embodiment, Schottky contact metal film 40 is disposed on insulating film 30 which has an opening and is disposed on group III nitride film 20 and, in Schottky contact metal film 40, Schottky contact portion 40a located in contact with the upper side of group III nitride film 20 under the opening of insulating film 30 is recessed relative to insulating contact portion 40b located in contact with the upper side of insulating film 30. Therefore, if Schottky contact metal film 40 and conductive support substrate 50 are directly joined together with joint metal film 60 interposed therebetween and the opening of insulating film 30 is large, a gap may be formed between the recessed portion of Schottky contact metal film 40 and joint metal film 60. Then, the step of disposing embedded metal film 80 between the recessed portion of Schottky contact metal film 40 and joint metal film 60 is performed so that embedded metal film 80 completely fills the space between the recessed portion of Schottky contact metal film 40 and joint metal film 60. In this way, occurrence of any gap between the recessed portion and joint metal film 60 can be prevented. Accordingly, the SBD can be improved in terms of the ON resistance, the breakdown voltage, and the yield determined by the appearance depending on for example whether group III nitride film 20 peels off or not, for example.

In the method of manufacturing an SBD in the seventh embodiment, the steps of: forming group III nitride film 20 on base group III nitride film 13 of base composite substrate 10 (FIG. 10 (A)); forming insulating film 30 having an opening on group III nitride film 20 (FIG. 10 (B)); and forming Schottky contact metal film 40 on group III nitride film 20 under the opening of insulating film 30 and on insulating film 30 (FIG. 10 (C)) are similar to the steps, in the method of manufacturing an SBD in the sixth embodiment, of: forming group III nitride film 20 on base group III nitride film 13 of base composite substrate 10 (FIG. 9 (A)); forming insulating film 30 having an opening on group III nitride film 20 (FIG. 9 (B)); and forming Schottky contact metal film 40 on group III nitride film 20 under the opening of insulating film 30 and on insulating film 30 (FIG. 9 (C)), respectively.

Referring to FIG. 10 (D), in the step of forming embedded metal film 80 on a recessed portion of Schottky contact metal film 40, the method of forming embedded metal film 80 is not particularly limited, and the following method or the like can be applied. Specifically, a resist mask (not shown) is formed by photolithography, a metal film made up of a plurality of layers is formed thereon through EB vapor deposition, resistance-heating vapor deposition, sputtering, or the like, and further the resist mask is lifted off. The step of forming embedded metal film 80 on the recessed portion of Schottky contact metal film 40 causes the recessed portion of Schottky contact metal film 40 to be reduced or planarized.

Referring to FIG. 10 (E), in the step of obtaining joined substrate 100 by joining conductive support substrate 50 onto Schottky contact metal film 40 and onto embedded metal film 80 with joint metal film 60 interposed therebetween, formation of embedded metal film 80 causes the recessed portion of Schottky contact metal film 40 to be reduced or planarized. Therefore, they are joined together by means of joint metal film 60 without causing a gap. The step of joining conductive support substrate 50 with joint metal film 60 interposed therebetween preferably includes the sub steps similar to those of the step of joining conductive support substrate 50 with joint metal film 60 interposed therebetween in the method of manufacturing an SBD in the sixth embodiment.

In the method of manufacturing an SBD in the seventh embodiment, the steps of: removing base composite substrate 10 from joined substrate 100 (FIG. 10 (F)); and forming first electrode 72 on group III nitride film 20 and forming second electrode 75 on conductive support substrate 50 (FIG. 10 (G)) are similar to the steps, in the method of manufacturing an SBD in the sixth embodiment, of: removing base composite substrate 10 from joined substrate 100 (FIG. 9 (E)); and forming first electrode 72 on group III nitride film 20 and forming second electrode 75 on conductive support substrate 50 (FIG. 9 (F)), respectively.

### Eighth Embodiment

Referring to FIG. 11, a method of manufacturing an SBD in an eighth embodiment of the present invention refers to a method of manufacturing the SBD in the third embodiment, and includes the steps of: forming group III nitride film 20 on base group III nitride film 13 of base composite substrate 10, base composite substrate 10 including base support substrate 11 and base group III nitride film 13 joined to one main-surface side of base support substrate 11 (FIG. 11 (A)); forming insulating film 30 having an opening on group III nitride film 20 (FIG. 11 (B)); forming Schottky contact metal film 40 on group III nitride film 20 under the opening of insulating film 30 and on insulating film 30 (FIG. 11 (C)); forming embedded metal film 80 on a recessed portion of Schottky contact metal film 40 (FIG. 11 (D)); forming anti-diffusion metal film 90 on Schottky contact metal film 40 and on embedded metal film 80 (FIG. 11 (E)); obtaining joined substrate 100 by joining conductive support substrate 50 onto anti-diffusion metal film 90 with joint metal film 60 interposed therebetween (FIG. 11 (F)); removing base composite substrate 10 from joined substrate 100 (FIG. 11 (G)); and forming first electrode 72 on group III nitride film 20 and forming second electrode 75 on conductive support substrate 50 (FIG. 11 (H)). In the step of forming Schottky contact metal film 40 (FIG. 11 (C)), Schottky contact metal film 40 is formed so that a part of Schottky contact metal film 40 extends on a part of insulating film 30.

Namely, the method of manufacturing an SBD in the eighth embodiment additionally includes, relative to the method of manufacturing an SBD in the seventh embodiment, the step of forming anti-diffusion metal film 90 on Schottky contact metal film 40 and on embedded metal film 80, after the step of forming embedded metal film 80 and before the step of obtaining joined substrate 100, and the step of obtaining joined substrate 100 is performed by joining conductive support substrate 50 onto anti-diffusion metal film 90 with joint metal film 60 interposed therebetween.

The method of manufacturing an SBD in the eighth embodiment includes the above-described steps to thereby enable the Schottky barrier diode having a high breakdown voltage and allowing large current to flow to be manufactured at low cost, like the method of manufacturing an SBD in the seventh embodiment. In addition, embedded metal film 80 completely fills the space between the recessed portion of Schottky contact metal film 40 and joint metal film 60. In this way, occurrence of any gap between the recessed portion and joint metal film 60 can be prevented. Accordingly, the SBD can be improved in terms of the ON resistance, the breakdown voltage, and the yield determined by the appearance depending on for example whether group III nitride film 20 peels off or not, for example.

Further, regarding the method of manufacturing an SBD in the eight embodiment, the step of forming anti-diffusion metal film 90 on Schottky contact metal film 40 and on embedded metal film 80, and the step of obtaining joined substrate 100 by joining conductive support substrate 50 onto anti-diffusion metal film 90 with joint metal film 60 interposed therebetween cause anti-diffusion metal film 90 to be formed between Schottky contact metal film 40 and joint metal film 60 and between embedded metal film 80 and joint metal film 60, and therefore, diffusion of metal atoms in joint metal film 60 into Schottky contact metal film 40 and into embedded metal film 80 can be prevented. Accordingly, the SBD is improved in terms of the forward threshold voltage, the ON resistance, the breakdown voltage, and the like.

In the method of manufacturing an SBD in the eighth embodiment, the steps of: forming group III nitride film 20 on base group III nitride film 13 of base composite substrate 10 (FIG. 11 (A)); forming insulating film 30 having an opening on group III nitride film 20 (FIG. 11 (B)); forming Schottky contact metal film 40 on group III nitride film 20 under the opening of insulating film 30 and on insulating film 30 (FIG. 11 (C)); and forming embedded metal film 80 on a recessed portion of Schottky contact metal film 40 (FIG. 11 (D)) are similar to the steps, in the method of manufacturing an SBD in the seventh embodiment, of: forming group III nitride film 20 on base group III nitride film 13 of base composite substrate 10 (FIG. 10 (A)); forming insulating film 30 having an opening on group III nitride film 20 (FIG. 10 (B)); forming Schottky contact metal film 40 on group III nitride film 20 under the opening of insulating film 30 and on insulating film 30 (FIG. 10 (C)); and forming embedded metal film 80 on a recessed portion of Schottky contact metal film 40 (FIG. 10 (D)).

Referring to FIG. 11 (E), in the step of forming anti-diffusion metal film 90 on Schottky contact metal film 40 and on embedded metal film 80, the method of forming anti-diffusion metal film 90 is not particularly limited, and a method of forming a metal film made up of a plurality of layers through EB vapor deposition, resistance-heating vapor deposition, sputtering, or the like, can be applied, for example.

Referring to FIG. 11 (F), in the step of obtaining joined substrate 100 by joining conductive support substrate 50 onto anti-diffusion metal film 90 with joint metal film 60 interposed therebetween, the step of joining conductive support substrate 50 with joint metal film 60 interposed is similar to the step of joining conductive support substrate 50 with joint metal film 60 interposed in the method of manufacturing an SBD in the sixth embodiment.

In the method of manufacturing an SBD in the eighth embodiment, the steps of: removing base composite substrate 10 from joined substrate 100 (FIG. 11 (G)); and forming first electrode 72 on group III nitride film 20 and forming second electrode 75 on conductive support substrate 50 (FIG. 11 (H)) are similar to the steps, in the method of manufacturing an SBD in the sixth embodiment, of: removing base composite substrate 10 from joined substrate 100 (FIG. 9 (E)); and forming first electrode 72 on group III nitride film 20 and forming second electrode 75 on conductive support substrate 50 (FIG. 9 (F)), respectively.

### Ninth Embodiment

Referring to FIG. 12, a method of manufacturing an SBD in a ninth embodiment of the present invention refers to a method of manufacturing the SBD in the fourth embodiment, and includes the steps of: forming group III nitride film 20 on base group III nitride film 13 of base composite substrate 10, base composite substrate 10 including base support substrate 11 and base group III nitride film 13 joined to one main-surface side of base support substrate 11 (FIG. 12 (A)); forming insulating film 30 having an opening on group III nitride film 20 (FIG. 12 (B)); forming Schottky contact metal film 40 on group III nitride film 20 under the opening of insulating film 30 and on insulating film 30 (FIG. 12 (C)); forming anti-diffusion metal film 90 on Schottky contact metal film 40 (FIG. 12 (D)); obtaining joined substrate 100 by joining conductive support substrate 50 onto anti-diffusion metal film 90 with joint metal film 60 interposed therebetween (FIG. 12 (E)); removing base composite substrate 10 from joined substrate 100 (FIG. 12 (F)); and forming first electrode 72 on group III nitride film 20 and forming second electrode 75 on conductive support substrate 50 (FIG. 12 (G)). In the step of forming Schottky contact metal film 40 (FIG. 12 (C)), Schottky contact metal film 40 is formed so that a part of Schottky contact metal film 40 extends on a part of insulating film 30.

Namely, the method of manufacturing an SBD in the ninth embodiment additionally includes, relative to the method of manufacturing an SBD in the sixth embodiment, the step of forming anti-diffusion metal film 90 on Schottky contact metal film 40, after the step of forming Schottky contact metal film 40 and before the step of obtaining joined substrate 100, and the step of obtaining joined substrate 100 is performed by joining conductive support substrate 50 onto anti-diffusion metal film 90 with joint metal film 60 interposed therebetween.

The method of manufacturing an SBD in the ninth embodiment includes the above-described steps to thereby enable the Schottky barrier diode having a high breakdown voltage and allowing large current to flow to be manufactured at low cost, like the method of manufacturing an SBD in the sixth embodiment.

Further, regarding the method of manufacturing an SBD in the ninth embodiment, the step of forming anti-diffusion metal film 90 on Schottky contact metal film 40 and the step of obtaining joined substrate 100 by joining conductive support substrate 50 onto anti-diffusion metal film 90 with joint metal film 60 interposed therebetween cause anti-diffusion metal film 90 to be formed between Schottky contact metal film 40 and joint metal film 60, and therefore, diffusion of metal atoms in joint metal film 60 into Schottky contact metal film 40 can be prevented. Accordingly, the SBD is improved in terms of the forward threshold voltage, the ON resistance, the breakdown voltage, and the like.

In the method of manufacturing an SBD in the ninth embodiment, the steps of: forming group III nitride film 20 on base group III nitride film 13 of base composite substrate 10 (FIG. 12 (A)); forming insulating film 30 having an opening on group III nitride film 20 (FIG. 12 (B)); and forming Schottky contact metal film 40 on group III nitride film 20 under the opening of insulating film 30 and on insulating film 30 (FIG. 12 (C)) are similar to the steps, in the method of manufacturing an SBD in the sixth embodiment, of: forming group III nitride film 20 on base group III nitride film 13 of base composite substrate 10 (FIG. 9 (A)); forming insulating film 30 having an opening on group III nitride film 20 (FIG. 9 (B)); and forming Schottky contact metal film 40 on group III nitride film 20 under the opening of insulating film 30 and on insulating film 30 (FIG. 9 (C)), respectively.

Referring to FIG. 12 (D), in the step of forming anti-diffusion metal film 90 on Schottky contact metal film 40, the method of forming anti-diffusion metal film 90 is similar to the method of forming anti-diffusion metal film 90 of the SBD in the eighth embodiment.

Anti-diffusion metal film 90 obtained in this way is formed on Schottky contact metal film 40 in which Schottky contact portion 40a formed on group III nitride film 20 under the opening of insulating film 30 is recessed relative to insulating contact portion 40b formed on insulating film 30. Therefore, in anti-diffusion metal film 90, a part formed on the recessed portion of Schottky contact metal film 40 is recessed relative to a part formed on a portion other than the recessed portion of Schottky contact metal film 40.

Referring to FIG. 12 (E), in the step of obtaining joined substrate 100 by joining conductive support substrate 50 onto anti-diffusion metal film 90 with joint metal film 60 interposed therebetween, the step of joining conductive support substrate 50 with joint metal film 60 interposed preferably includes sub steps similar to those of the step of joining conductive support substrate 50 with joint metal film 60 interposed in the method of manufacturing an SBD in the sixth embodiment. In this case, the recessed portion of anti-diffusion metal film 90 is filled with joint metal film 60. Particularly in the case where the opening of insulating film 30 is small, the recessed portion of anti-diffusion metal film 90 is completely filled with joint metal film 60.

In the method of manufacturing an SBD in the ninth embodiment, the steps of: removing base composite substrate 10 from joined substrate 100 (FIG. 12 (F)); and forming first electrode 72 on group III nitride film 20 and forming second electrode 75 on conductive support substrate 50 (FIG. 12 (G)) are similar to the steps, in the method of manufacturing an SBD in the sixth embodiment, of: removing base composite substrate 10 from joined substrate 100 (FIG. 9 (E)); and forming first electrode 72 on group III nitride film 20 and forming second electrode 75 on conductive support substrate 50 (FIG. 9 (F)), respectively.

### Tenth Embodiment

Referring to FIG. 13, a method of manufacturing an SBD in a tenth embodiment of the present invention refers to a method of manufacturing the SBD in the fifth embodiment, and includes the steps of: forming group III nitride film 20 on base group III nitride film 13 of base composite substrate 10, base composite substrate 10 including base support substrate 11 and base group III nitride film 13 joined to one main-surface side of base support substrate 11 (FIG. 13 (A)); forming insulating film 30 having an opening on group III nitride film 20 (FIG. 13 (B)); forming Schottky contact metal film 40 on group III nitride film 20 under the opening of insulating film 30 and on insulating film 30 (FIG. 13 (C)); forming anti-diffusion metal film 90 on Schottky contact metal film 40 (FIG. 13 (D)); forming embedded metal film 80 on a recessed portion of anti-diffusion metal film 90 (FIG. 13 (E)); obtaining joined substrate 100 by joining conductive support substrate 50 onto anti-diffusion metal film 90 and embedded metal film 80 with joint metal film 60 interposed therebetween (FIG. 13 (F)); removing base composite substrate 10 from joined substrate 100 (FIG. 13 (G)); and forming first electrode 72 on group III nitride film 20 and forming second electrode 75 on conductive support substrate 50 (FIG. 13 (H)). In the step of forming Schottky contact metal film 40 (FIG. 13 (C)), Schottky contact metal film 40 is formed so that a part of Schottky contact metal film 40 extends on a part of insulating film 30.

Namely, the method of manufacturing an SBD in the tenth embodiment additionally includes, relative to the method of manufacturing an SBD in the ninth embodiment, the step of forming embedded metal film 80 on a recessed portion of anti-diffusion metal film 90, after the step of forming anti-diffusion metal film 90 and before the step of obtaining joined substrate 100, and the step of obtaining joined substrate 100 is performed by joining conductive support substrate 50 onto anti-diffusion metal film 90 and onto embedded metal film 80 with joint metal film 60 interposed therebetween.

The method of manufacturing an SBD in the tenth embodiment includes the above-described steps to thereby enable the Schottky barrier diode having a high breakdown voltage and allowing large current to flow to be manufactured at low cost, like the method of manufacturing an SBD in the ninth embodiment. In addition, because anti-diffusion metal film 90 is formed between Schottky contact metal film 40 and joint metal film 60, diffusion of metal atoms in joint metal film 60 into Schottky contact metal film 40 can be prevented. Accordingly, the SBD is improved in terms of the forward threshold voltage, the ON resistance, the breakdown voltage, and the like.

Further, regarding the method of manufacturing an SBD in the tenth embodiment, anti-diffusion metal film 90 is formed on Schottky contact metal film 40 in which Schottky contact portion 40a formed on group III nitride film 20 under the opening of insulating film 30 is recessed relative to insulating contact portion 40b formed on insulating film 30. Thus, in anti-diffusion metal film 90, a part formed on the recessed portion of Schottky contact metal film 40 is recessed relative to a part formed on a portion other than the recessed portion of Schottky contact metal film 40. Therefore, if anti-diffusion metal film 90 and conductive support substrate 50 are directly joined together with joint metal film 60 interposed therebetween and the opening of insulating film 30 is large, namely the recessed portion of Schottky contact metal film 40 is large, a gap may be formed between the recessed portion of anti-diffusion metal film 90 and joint metal film 60. Then, the step of forming embedded metal film 80 on the recessed portion of anti-diffusion metal film 90 and obtaining joined substrate 100 by joining conductive support substrate 50 onto anti-diffusion metal film 90 and onto embedded metal film 80 with joint metal film 60 interposed therebetween are performed. Thus, embedded metal film 80 completely fills the space between the recessed portion of anti-diffusion metal film 90 and joint metal film 60 to thereby prevent occurrence of a gap therebetween. Accordingly, the SBD can be improved in terms of the ON resistance, the breakdown voltage, and the yield determined by the appearance depending on for example whether group III nitride film 20 peels off or not, for example.

In the method of manufacturing an SBD in the tenth embodiment, the steps of: forming group III nitride film 20 on base group III nitride film 13 of base composite substrate 10 (FIG. 13 (A)); forming insulating film 30 having an opening on group III nitride film 20 (FIG. 13 (B)); forming Schottky contact metal film 40 on group III nitride film 20 under the opening of insulating film 30 and on insulating film 30 (FIG. 13 (C)); and forming anti-diffusion metal film 90 on Schottky contact metal film 40 (FIG. 13 (D)) are similar to the steps, in the method of manufacturing an SBD in the ninth embodiment, of: forming group III nitride film 20 on base group III nitride film 13 of base composite substrate 10 (FIG. 12 (A)); forming insulating film 30 having an opening on group III nitride film 20 (FIG. 12 (B)); forming Schottky contact metal film 40 on group III nitride film 20 under the opening of insulating film 30 and on insulating film 30 (FIG. 12 (C)); and forming anti-diffusion metal film 90 on Schottky contact metal film 40 (FIG. 12 (D)), respectively.

Referring to FIG. 13 (E), in the step of forming embedded metal film 80 on a recessed portion of anti-diffusion metal film 90, the method of forming embedded metal film 80 is similar to the method of forming embedded metal film 80 in the method of manufacturing an SBD in the seventh embodiment. The step of forming embedded metal film 80 on the recessed portion of anti-diffusion metal film 90 causes the recessed portion of anti-diffusion metal film 90 to be reduced or planarized.

Referring to FIG. 13 (F), in the step of obtaining joined substrate 100 by joining conductive support substrate 50 onto anti-diffusion metal film 90 and onto embedded metal film 80 with joint metal film 60 interposed therebetween, the formation of embedded metal film 80 causes the recessed portion of anti-diffusion metal film 90 to be reduced or planarized. Thus, they are joined together through joint metal film 60 without causing gaps. The step of joining conductive support substrate 50 with joint metal film 60 interposed preferably includes sub steps similar to those of the step of joining conductive support substrate 50 with joint metal film 60 interposed in the method of manufacturing an SBD in the sixth embodiment.

In the method of manufacturing an SBD in the tenth embodiment, the steps of: removing base composite substrate 10 from joined substrate 100 (FIG. 13 (G)); and forming first electrode 72 on group III nitride film 20 and forming second electrode 75 on conductive support substrate 50 (FIG. 13 (H)) are similar to the steps, in the method of manufacturing an SBD in the sixth embodiment, of: removing base composite substrate 10 from joined substrate 100 (FIG. 9 (E)); and forming first electrode 72 on group III nitride film 20 and forming second electrode 75 on conductive support substrate 50 (FIG. 9 (F)), respectively.

Referring to FIG. 9 (F), FIG. 10 (G), FIG. 11 (H), FIG. 12 (G), and FIG. 13 (H), regarding the methods of manufacturing SBDs in the sixth to tenth embodiments, in order to facilitate alignment in fabrication of the SBD into a chip, preferably first electrode 72 is patterned so that first electrode 72 is located on a part of a main surface of group III nitride film 20. The method of patterning first electrode 72 is not particularly limited. For the sake of efficient patterning, photolithography or the like is appropriate.

### EXAMPLES

### Example 1

Example 1 corresponds to the SBD in the first embodiment and the method of manufacturing the SBD in the sixth embodiment.

1. Formation of Group III Nitride Film

Referring first to FIG. 9 (A), base composite substrate 10 including base support substrate 11 with a thickness of 450 μm, base joint film 12 formed of an SiO₂ film with a thickness of 400 nm disposed on one main surface of base support substrate 11, and base group III nitride film 13 formed of a GaN film with a thickness of 150 nm disposed on base joint film 12 was prepared. The main surface of the base group III nitride film was a Ga atomic plane which was (0001) plane. This base composite substrate 10 was obtained, as shown in FIG. 14, by bonding together base support substrate 11 and a base group III nitride film mother substrate 13D in which an ion implantation region is formed, with base joint film 12 interposed therebetween, and thereafter separating base group III nitride film mother substrate 13D along ion implantation region 13i into base group III nitride film 13 and a remaining base group III nitride film mother substrate 30E. Base group III nitride film 13 had a low dislocation density on the order of 1×10⁵ cm⁻² and high crystallinity.

As base composite substrate 10, three different base composite substrates including the following three different substrates respectively as base support substrate 11 were prepared. As base support substrate 11, three different substrates that were molybdenum substrate, mullite substrate, and yttria stabilized zirconia-mullite substrate were prepared. As to the chemical composition of the mullite substrate, it included 64 mol % of Al₂O₃ and 36 mol % of SiO₂. As to the chemical composition of the yttria stabilized zirconia-mullite substrate, it included 30 mass % of yttria stabilized zirconia and 70 mass % of mullite. As to the chemical composition of yttria stabilized zirconia, it included 10 mol % of Y₂O₃ and 90 mol % of ZrO₂. As to the chemical composition of mullite, it included 60 mol % of Al₂O₃ and 40 mol % of SiO₂. These base support substrates 11 each had a diameter of two inches (5.08 cm) and a thickness of 450 μm, and had its main surface subjected to precise mirror polishing so that its roughness Ra (Roughness Ra herein means arithmetic mean roughness Ra defined under JIS B0601:2001, and the same is applied hereinafter as well) was less than 10 nm. Further, the thermal expansion coefficient of the molybdenum substrate and the yttria stabilized zirconia-mullite substrate was identical to the thermal expansion coefficient of GaN, over a temperature range from room temperature (25° C.) to 1200° C. The thermal expansion coefficient of the mullite substrate was 80% of the thermal expansion coefficient of GaN, over a temperature range from room temperature (25° C.) to 1200° C.

Next, on base group III nitride film 13 of base composite substrate 10, MOCVD was applied to form, as group III nitride film 20, an n⁺-group III nitride layer 21 formed of an n⁺-GaN layer having a thickness of 1 μm and a donor concentration of 1.5×10¹⁸ cm⁻³ and an n-group III nitride layer 22 formed of an n-GaN layer having a thickness of 7 μm and a donor concentration of 5.5×10¹⁵ cm⁻³. Regarding obtained group III nitride film 20, no crack occurred and it had a low dislocation density as measured through CL (cathode luminescence) on the order of 10⁵ cm⁻².

2. Formation of Insulating Film Having Opening

Referring next to FIG. 9 (B), on group III nitride film 20, plasma CVD was applied to form insulating film 30 formed of an Si₃N₄ film with a thickness of 500 nm, using silane gas and ammonia gas as material gases. Subsequently, an RTA (rapid thermal anneal) furnace was used to perform annealing under a nitrogen atmosphere at 600° C. for three minutes.

Next, a resist mask formed on insulating film 30 by photolithography was used to perform etching for 15 minutes with buffered hydrofluoric acid (referring to a mixture of an aqueous solution of 50 mass % hydrofluoric acid and an aqueous solution of 40 mass % ammonium fluoride at a mass ratio of 1:5) to remove insulating film 30 in an opening of the resist mask. After etching, the resist mask was removed by means of acetone. In this way, insulating film 30 was formed as a field plate in a shape in plan view of 200 μm×5000 μm having a rectangular opening with arc-shaped vertexes having a radius of curvature of 50 μ.

3. Formation of Schottky Contact Metal Film

Referring next to FIG. 9 (C), a resist mask was formed by photolithography on insulating film 30 having an opening. An Ni layer with a thickness of 500 angstrom and an Au layer with a thickness of 3000 angstrom were successively formed by EB vapor deposition on group III nitride film 20 under the opening of insulating film 30 and on insulating film 30, patterned by lifting off the resist mask with acetone, and then annealed in a nitrogen atmosphere at 400° C. for three minutes by means of an RTA (rapid thermal anneal) furnace into an alloy. Thus, Schottky contact metal film 40 was formed in such a manner that a part of Schottky contact metal film 40 extended on a part of insulating film 30. The part of Schottky contact metal film 40 extending on the part of insulating film 30 had a width (hereinafter referred to as the width of insulating contact portion 40b of Schottky contact metal film 40) of 15 μm.

4. Formation of Joined Substrate

Referring next to FIG. 9 (D), an Si substrate having a thickness of two inches (5.08 cm) and a thickness of 320 μm was prepared as conductive support substrate 50. This Si substrate had a resistance of less than 0.001 Ωcm and was doped with p-type.

Next, on conductive support substrate 50, EB vapor deposition was applied to form an Ni layer with a thickness of 500 angstrom, a Pt layer with a thickness of 4000 angstrom, and an Au layer with a thickness of 500 angstrom as joint metal film 60. Further, on this metal film, resistance-heating vapor deposition was applied to form an Au—Sn layer (chemical composition: 70 mass % of Au and 30 mass % of Sn) with a thickness of 5 μm.

Next, the Au layer of Schottky contact metal film 40 and the Au—Sn layer of joint metal film 60 were joined together by means of a wafer bonder to thereby obtain joined substrate 100. The conditions for joining were a vacuum atmosphere of less than 1 Pa, a temperature of 300° C., and a time for joining of 10 minutes. After they were joined together, an ultrasonic microscope was used to confirm that the joint surface had no defect (remaining void) or the like.

5. Removal of Base Composite Substrate from Joined Substrate

Referring next to FIG. 9 (E), base composite substrate 10 was removed from joined substrate 100 by removing base support substrate 11, base joint film 12, and base group III nitride film 13.

In the case where base support substrate 11 was the molybdenum substrate, a sapphire substrate (not shown) having a diameter of three inches (7.62 cm) and a thickness of 500 μm was prepared. To this sapphire substrate, the Si substrate of conductive support substrate 50 of joined substrate 100 was bonded with a wax interposed therebetween, and the outer side surface thereof was also protected with the wax. Next, an aqueous solution of 35 mass % nitric acid was prepared. In the nitric acid aqueous solution stirred at 200 rpm, joined substrate 100 bonded to the sapphire substrate was immersed for 40 minutes to thereby etch away the molybdenum substrate which was the base support substrate. The resultant substrate was washed with hydrochloric acid and pure water. Subsequently, it was immersed in buffered hydrofluoric acid for 10 minutes to thereby etch away the SiO₂ film which was base joint film 12. On the substrate thus obtained, the base GaN film which was base group III nitride film 13 was exposed.

In the case where base support substrate 11 was the mullite substrate, the mullite substrate which was base support substrate 11 of joined substrate 100 was ground with a surface grinding machine so that the thickness became 40 μm. Next, a sapphire substrate (not shown) having a diameter of three inches (7.62 cm) and a thickness of 500 μm was prepared. To this sapphire substrate, the Si substrate of conductive support substrate 50 of joined substrate 100 was bonded with a wax interposed therebetween, and the outer side surface thereof was also protected with the wax. Next, an aqueous solution of 50 mass % hydrofluoric acid was prepared. In the hydrofluoric acid aqueous solution stirred at 200 rpm, joined substrate 100 bonded to the sapphire substrate was immersed for 30 minutes to thereby etch away the SiO₂ film which was base joint film 12 and accordingly lift off the mullite substrate which was base support substrate 11. On the substrate thus obtained, the base GaN film which was base group III nitride film 13 was exposed.

In the case where base support substrate 11 was the yttria stabilized zirconia-mullite substrate, the yttria stabilized zirconia-mullite substrate which was base support substrate 11 of joined substrate 100 was ground with a surface grinding machine so that the thickness became 40 μm. Next, a sapphire substrate (not shown) having a diameter of three inches (7.62 cm) and a thickness of 500 μm was prepared. To this sapphire substrate, the Si substrate of conductive support substrate 50 of joined substrate 100 was bonded with a wax interposed therebetween, and the outer side surface thereof was also protected with the wax. Next, an aqueous solution of 50 mass % hydrofluoric acid was prepared. In the hydrofluoric acid aqueous solution stirred at 200 rpm, joined substrate 100 bonded to the sapphire substrate was immersed for eight hours to thereby etch away the SiO₂ film which was base joint film 12 and accordingly lift off the mullite substrate which was base support substrate 11. On the substrate thus obtained, the base GaN film which was base group III nitride film 13 was exposed.

Next, the base GaN film which was base group III nitride film 13 under the obtained substrate was etched away by ICP-RIE using chlorine gas as etching gas.

6. Formation of First Electrode and Second Electrode

Referring next to FIG. 9 (F), a resist mask was formed by photolithography on group III nitride film 20 of the obtained substrate. On this film, EB vapor deposition was applied to successively form a Ti layer with a thickness of 200 angstrom, an Al layer with a thickness of 300 angstrom, a Ti layer again with a thickness of 200 angstrom, and finally an Au layer with a thickness of 3000 angstrom, to thereby form first electrode 72 in the shape in plan view of a rectangle of 300 μm×5100 μm. On conductive support substrate 50 of the obtained substrate, EB vapor deposition was applied to successively form a Ti layer with a thickness of 200 angstrom, a Pt layer with a thickness of 300 angstrom, and an Au layer with a thickness of 3000 angstrom, to thereby form second electrode 75. Next, RTA was used to anneal first electrode 72 and second electrode 75 under a nitrogen atmosphere at 250° C. for three minutes.

The SBD thus obtained was bonded onto a UV-curable dicing tape so that first electrode 72 formed on group III nitride film 20 was directed downward. The Si substrate which was conductive support substrate 50 was cut from its main surface to a depth of 300 μm with a dicer in accordance with a chip pattern. Subsequently, the cut portion was broken with a breaker so that the remaining portion was separated. Accordingly it was fabricated into an SBD chip having a main surface of 400 μm×5200 μm.

The SBD chip thus obtained was measured with a curve tracer. It had a breakdown voltage against reverse bias of 600 V or more. In a forward bias operation, 5 A or more could be successfully flown through an electrode pattern chip of 1 mm².

### Example 2

Example 2 corresponds to the SBD in the second embodiment and the method of manufacturing the SBD in the seventh embodiment.

1. Formation of Group III Nitride Film, Formation of Insulating Film Having Opening, and Formation of Schottky Contact Metal Film

Referring to FIG. 10 (A) to (C), group III nitride film 20 was formed, insulating film 30 was formed in a shape in plan view of 1000 μm×1000 μm having a square opening with arc-shaped vertexes having a radius of curvature of 100 μm, and Schottky contact metal film 40 was formed on the group III nitride film under the opening of insulating film 30 and on a part of the insulating film, so that insulating contact portion 40b of Schottky contact metal film 40 had a width of 30 μm, similarly to Example 1.

2. Formation of Embedded Metal Film

Referring to FIG. 10 (D), on the recessed portion of Schottky contact metal film 40, a resist mask (not shown) was formed by photolithography, and an Ni layer with a thickness of 4500 angstrom and an Au layer with a thickness of 500 angstrom were successively formed thereon by EB vapor deposition, to thereby form embedded metal film 80 in a square shape in plan view of 990 μm×990 μm having arc-shaped vertexes with a radius of curvature of 95 μm.

3. Formation of Joined Substrate, Removal of Base Composite Substrate from Joined Substrate, and Formation of First Electrode and Second Electrode

Referring to FIG. 10 (E) to (G), joined substrate 100 was formed, base composite substrate 10 was removed from joined substrate 100, and first electrode 72 and second electrode 75 were formed, similarly to Example 1. Further, it was fabricated into a chip and accordingly the SBD chip with a main surface of 1500 μm×1500 μm was obtained.

The SBD chip thus obtained was measured with a curve tracer. It had a breakdown voltage against reverse bias of 600 V or more. In a forward bias operation, 5 A or more could be successfully flown through an electrode pattern chip of 1 mm².

### Example 3

Example 3 corresponds to the SBD in the third embodiment and the method of manufacturing the SBD in the eighth embodiment.

1. Formation of Group III Nitride Film, Formation of Insulating Film Having Opening, Formation of Schottky Contact Metal Film, and Formation of Embedded Metal Film

Referring to FIG. 11 (A) to (D), group III nitride film 20 was formed, insulating film 30 was formed in a shape in plan view of 1000 μm×1000 μm having a square opening with arc-shaped vertexes having a radius of curvature of 100 μm, Schottky contact metal film 40 was formed on the group III nitride film under the opening of insulating film 30 and on a part of the insulating film, so that insulating contact portion 40b of Schottky contact metal film 40 had a width of 30 μm, and embedded metal film 80 was formed in a square shape in plan view of 990 μm×990 μm having arc-shaped vertexes with a radius of curvature of 95 μm, similarly to Example 2.

2. Formation of Anti-Diffusion Metal Film

Referring to FIG. 11 (E), on Schottky contact metal film 40 and on embedded metal film 80, EB vapor deposition was applied to successively form an Ni layer with a thickness of 500 angstrom, a Pt layer with a thickness of 4000 angstrom, and an Au layer with a thickness of 500 angstrom, to thereby form anti-diffusion metal film 90.

3. Formation of Joined Substrate, Removal of Base Composite Substrate from Joined Substrate, and Formation of First Electrode and Second Electrode

Referring to FIG. 11 (F) to (H), joined substrate 100 was formed, base composite substrate 10 was removed from joined substrate 100, and first electrode 72 and second electrode 75 were formed, similarly to Example 1. Further, it was fabricated into a chip and accordingly the SBD chip with a main surface of 1500 μm×1500 μm was obtained.

The SBD chip thus obtained was measured with a curve tracer. It had a breakdown voltage against reverse bias of 600 V or more. In a forward bias operation, 5 A or more could be successfully flown through an electrode pattern chip of 1 mm².

### Example 4

Example 4 corresponds to the SBD in the fourth embodiment and the method of manufacturing the SBD in the ninth embodiment.

1. Formation of Group III Nitride Film, Formation of Insulating Film Having Opening, and Formation of Schottky Contact Metal Film

Referring to FIG. 12 (A) to (C), group III nitride film 20 was formed, insulating film 30 was formed in a shape in plan view of 200 μm×5000 μm having a rectangular opening with arc-shaped vertexes having a radius of curvature of 50 μm, and Schottky contact metal film 40 was formed on the group III nitride film under the opening of insulating film 30 and on a part of the insulating film, so that insulating contact portion 40b of Schottky contact metal film 40 had a width of 15 μm, similarly to Example 1.

2. Formation of Anti-Diffusion Metal Film

Referring to FIG. 12 (D), on Schottky contact metal film 40, EB vapor deposition was applied to successively form an Ni layer with a thickness of 500 angstrom, a Pt layer with a thickness of 4000 angstrom, and an Au layer with a thickness of 500 angstrom, to thereby form anti-diffusion metal film 90.

3. Formation of Joined Substrate, Removal of Base Composite Substrate from Joined Substrate, and Formation of First Electrode and Second Electrode

Referring to FIG. 12 (E) to (G), joined substrate 100 was formed, base composite substrate 10 was removed from joined substrate 100, and first electrode 72 and second electrode 75 were formed, similarly to Example 1. Further, it was fabricated into a chip and accordingly the SBD chip with a main surface of 400 μm×5200 μm was obtained.

The SBD chip thus obtained was measured with a curve tracer. It had a breakdown voltage against reverse bias of 600 V or more. In a forward bias operation, 5 A or more could be successfully flown through an electrode pattern chip of 1 mm².

### Example 5

Example 5 corresponds to the SBD in the fifth embodiment and the method of manufacturing the SBD in the tenth embodiment.

1. Formation of Group III Nitride Film, Formation of Insulating Film Having Opening, Formation of Schottky Contact Metal Film, and Formation of Anti-Diffusion Metal Film

Referring to FIG. 13 (A) to (D), group III nitride film 20 was formed, insulating film 30 was formed in a shape in plan view of 1000 μm×1000 μm having a square opening with arc-shaped vertexes having a radius of curvature of 100 μm, Schottky contact metal film 40 was formed on the group III nitride film under the opening of insulating film 30 and on a part of the insulating film, so that insulating contact portion 40b of Schottky contact metal film 40 had a width of 30 μm, and anti-diffusion metal film 90 was formed, similarly to Example 4.

2. Formation of Embedded Metal Film

Referring to FIG. 13 (E), on the recessed portion of anti-diffusion metal film 90, a resist mask (not shown) was formed by photolithography, and an Ni layer with a thickness of 4500 angstrom and an Au layer with a thickness of 500 angstrom were successively formed thereon by EB vapor deposition, to thereby form embedded metal film 80 in a square shape in plan view of 990 μm×990 μm having arc-shaped vertexes with a radius of curvature of 95 μm.

3. Formation of Joined Substrate, Removal of Base Composite Substrate from Joined Substrate, and Formation of First Electrode and Second Electrode

Referring to FIG. 13 (F) to (H), joined substrate 100 was formed, base composite substrate 10 was removed from joined substrate 100, and first electrode 72 and second electrode 75 were formed, similarly to Example 1. Further, it was fabricated into a chip and accordingly the SBD chip with a main surface of 1500 μm×1500 μm was obtained.

The SBD chip thus obtained was measured with a curve tracer. It had a breakdown voltage against reverse bias of 600 V or more. In a forward bias operation, 5 A or more could be successfully flown through an electrode pattern chip of 1 mm².

It should be construed that the embodiments and examples disclosed herein are given by way of illustration in all respects, not by way of limitation. It is intended that the scope of the present invention is defined by claims, not by the description above, and encompasses all modifications and variations equivalent in meaning and scope to the claims.

### REFERENCE SIGNS LIST

10 base composite substrate; 11 base support substrate; 11m, 13n main surface; 12, 12a, 12b base joint film; 13 base group III nitride film; 13D base group III nitride film mother substrate; 13i ion implantation region; 20 group III nitride film; 21 n⁺-GaN layer; 22 n-GaN layer; 30 insulating film; 40 Schottky contact metal film; 40a Schottky contact portion; 40b insulating contact portion; 50 conductive support substrate; 60 joint metal film; 72 first electrode; 75 second electrode; 80 embedded metal film; 90 anti-diffusion metal film; 100 joined substrate

1. A Schottky barrier diode comprising a first electrode, a group III nitride film, an insulating film having an opening, a Schottky contact metal film, a joint metal film, a conductive support substrate, and a second electrode that are arranged in order in a direction from a first main-surface side to a second main-surface side.

2. The Schottky barrier diode according to claim 1, wherein a part of said Schottky contact metal film extends on a part of said insulating film.

3. The Schottky barrier diode according to claim 2, further comprising an embedded metal film disposed between said joint metal film and a recessed portion of said Schottky contact metal film, said recessed portion being formed by presence of said opening of said insulating film.

4. The Schottky barrier diode according to claim 3, further comprising an anti-diffusion metal film disposed between said Schottky contact metal film and said joint metal film and between said embedded metal film and said joint metal film.

5. The Schottky barrier diode according to claim 2, further comprising an anti-diffusion metal film disposed between said Schottky contact metal film and said joint metal film.

6. The Schottky barrier diode according to claim 5, further comprising an embedded metal film disposed between said joint metal film and a recessed portion of said anti-diffusion metal film, said recessed portion being formed by presence of the opening of said insulating film.

7. The Schottky barrier diode according to claim 2, wherein said first electrode is located on a part of a main surface of said group III nitride film.

8. A method of manufacturing a Schottky barrier diode comprising the steps of:
forming a group III nitride film on a base group III nitride film of a base composite substrate, said base composite substrate including a base support substrate and said base group III nitride film joined to one main-surface side of said base support substrate;
forming an insulating film having an opening on said group III nitride film;
forming a Schottky contact metal film on said group III nitride film under the opening of said insulating film and on said insulating film;
obtaining a joined substrate by joining a conductive support substrate onto said Schottky contact metal film with a joint metal film interposed therebetween;
removing said base composite substrate from said joined substrate; and
forming a first electrode on said group III nitride film and forming a second electrode on said conductive support substrate.

9. The method of manufacturing a Schottky barrier diode according to claim 8, wherein in said step of forming a Schottky contact metal film, said Schottky contact metal film is formed so that a part of said Schottky contact metal film extends on a part of said insulating film.

10. The method of manufacturing a Schottky barrier diode according to claim 9, further comprising the step of forming an embedded metal film on a recessed portion of said Schottky contact metal film, after said step of forming a Schottky contact metal film and before said step of obtaining a joined substrate, wherein
said step of obtaining a joined substrate is performed by joining said conductive support substrate onto said Schottky contact metal film and onto said embedded metal film with said joint metal film interposed therebetween.

11. The method of manufacturing a Schottky barrier diode according to claim 10, further comprising the step of forming an anti-diffusion metal film on said Schottky contact metal film and on said embedded metal film, after said step of forming an embedded metal film and before said step of obtaining a joined substrate, wherein
said step of obtaining a joined substrate is performed by joining said conductive support substrate onto said anti-diffusion metal film with said joint metal film interposed therebetween.

12. The method of manufacturing a Schottky barrier diode according to claim 9, further comprising the step of forming an anti-diffusion metal film on said Schottky contact metal film, after said step of forming a Schottky contact metal film and before said step of obtaining a joined substrate, wherein
said step of obtaining a joined substrate is performed by joining said conductive support substrate onto said anti-diffusion metal film with said joint metal film interposed therebetween.

13. The method of manufacturing a Schottky barrier diode according to claim 12, further comprising the step of forming an embedded metal film on a recessed portion of said anti-diffusion metal film, after said step of forming an anti-diffusion metal film and before said step of obtaining a joined substrate, wherein
said step of obtaining a joined substrate is performed by joining said conductive support substrate onto said anti-diffusion metal film and onto said embedded metal film with said joint metal film interposed therebetween.

14. The method of manufacturing a Schottky barrier diode according to claim 9, wherein said first electrode is formed on a part of a main surface of said group III nitride film.
